(19) United States
(12) Patent Application Publication
(10) Pub. No.: US 2021/0287721 A1
(43) Pub. Date: Sep. 16, 2021

(54) DISK DRIVE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kouichi TOUKAIRIN, Kawasaki Kanagawa (JP)

(21) Appl. No.: 17/011,819

(22) Filed: Sep. 3, 2020

(30) Foreign Application Priority Data
Mar. 10, 2020 (JP) 2020-040798

(51) Int. Cl. G11B 33/14; H05K 7/20; H05K 5/04; G11B 33/12

(52) U.S. Cl. CPC G11B 33/1426; H05K 7/20436; G11B 33/122; G11B 33/123; H05K 5/04

(57) ABSTRACT

A disk drive includes a case having an outer surface, a recording medium and a magnetic head disposed inside the case, a board disposed outside the case and is electrically connected to the magnetic head, an electronic component mounted on a mounting surface of the board that faces the outer surface, and a heat conduction member having a hole and compressed between the electronic component and the outer surface in a thickness direction of the disk drive to thermally couple the electronic component to the case.

### CROSS-REFERENCE TO RELATED APPLICATION(S)

This application is based upon and claims the benefit of priority from Japanese Patent Application No. 2020-040798, filed Mar. 10, 2020, the entire contents of which are incorporated herein by reference.

### FIELD

Embodiments described herein relate generally to a disk drive.

### BACKGROUND

Disk drives, such as hard disk drives (HDDs), include a magnetic disk, a magnetic head for reading and writing information from and to the magnetic disk, and a board mounted with various kinds of electronic components. The electronic components, which generate heat, are thermally coupled to a heat sink or a case of an HDD so as to be cooled.

Electronic components may be thermally coupled to a case via a heat conductive member. The heat conductive member is compressed, for example, between an electronic component and a wall of the case, and applies reaction forces to the electronic component and a board on which the electronic component is mounted. The reaction forces increase as deformability of the heat conductive member decreases.

### BRIEF DESCRIPTION OF THE DRAWINGS

FIG. 1 is a perspective view showing an example of a hard disk drive (HDD) according to a first embodiment.

FIG. 2 is a sectional view schematically showing a part of the HDD of the first embodiment.

FIG. 3 is an exploded perspective view of a bottom wall, a controller, and a heat dissipation sheet in the HDD according to the first embodiment.

FIG. 4 is a plan view schematically showing a bottom wall, a controller, and a heat dissipation sheet in an HDD according to a modification example of the first embodiment.

FIG. 5 is an exploded perspective view of a bottom wall, a controller, and a heat dissipation sheet in an HDD according to a second embodiment.

FIG. 6 is a perspective view schematically showing a heat dissipation sheet in an HDD according to a third embodiment.

FIG. 7 is a plan view schematically showing a bottom wall, a controller, and a heat dissipation sheet in an HDD according to a first modification example of the third embodiment.

FIG. 8 is a plan view schematically showing a bottom wall, a controller, and a heat dissipation sheet in an HDD according to a second modification example of the third embodiment.

### DETAILED DESCRIPTION

Embodiments provide a disk drive including a heat conduction member that applies relatively small reaction forces to electronic components and a board on which the electronic components are mounted.

In general, according to one embodiment, a disk drive includes a case, a recording medium, a magnetic head, a board, an electronic component, and a heat conduction member. The case has an outer surface. The recording medium is disposed inside the case and has a recording layer. The magnetic head is disposed inside the case and is configured to read and write information from and to the recording medium. The board is disposed outside the case, has a mounting surface that faces the outside surface, and is electrically connected to the magnetic head. The electronic component is mounted on the mounting surface. The heat conduction member includes a hole and is compressed between the electronic component and the outer surface in a thickness direction of the disk drive to thermally couple the electronic component to the case.

### First Embodiment

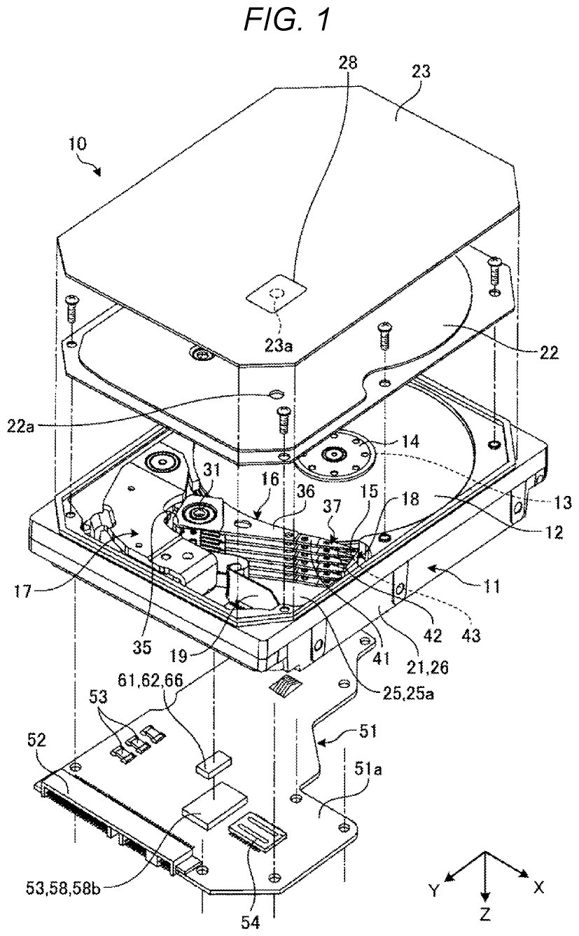

Hereinafter, a first embodiment will be described with reference to FIGS. 1 to 3. In the present specification, elements according to embodiments and description of the elements may be described using several different expressions. The elements and the description of the elements are given by way of examples and are not limited to the expressions used in the present specification. The elements may be identified by terms different from those used in the present specification. In addition, the elements may be described using expressions different from those in the present specification.

FIG. 1 is a perspective view showing an example of a hard disk drive (HDD) 10 according to the first embodiment. The HDD 10 is an example of a disk drive and may also be called an “electronic device”, a “storage device”, an “external storage device”, or a “magnetic disk drive”.

As shown in each drawing, an X-axis, a Y-axis, and a Z-axis are defined for convenience in the present specification. The X-axis, the Y-axis, and the Z-axis are orthogonal to each other. The X-axis is defined along the width of the HDD 10. The Y-axis is defined along the length of the HDD 10. The Z-axis is defined along the thickness of the HDD 10.

An X direction, a Y direction, and a Z direction are defined in the present specification. The X direction is along the X-axis and includes a +X direction, which is indicated by the arrow of the X-axis, and a −X direction, which is an opposite direction of the arrow of the X-axis.

The Y direction is along the Y-axis and includes a +Y direction, which is indicated by the arrow of the Y-axis, and a −Y direction, which is an opposite direction of the arrow of the Y-axis. The Z direction is along the Z-axis and includes a +Z direction, which is indicated by the arrow of the Z-axis, and a −Z direction, which is an opposite direction of the arrow of the Z-axis.

The HDD 10 includes a case 11, multiple magnetic disks 12, a spindle motor 13, a clamp spring 14, multiple magnetic heads 15, an actuator assembly 16, a voice coil motor (VCM) 17, a ramp load mechanism 18, and a flexible printed circuit (FPC) board 19. The magnetic disk 12 is an example of a recording medium.

The case 11 includes a base 21, an inner cover 22, and an outer cover 23. The base 21 is a closed-bottom container and includes a bottom wall 25 and a side wall 26. The bottom wall 25 may also be called, for example, a “wall” or a “plate”.

The bottom wall 25 is formed into an approximately rectangular or square plate shape. The side wall 26 protrudes upwards from an edge of the bottom wall 25. The bottom wall 25 and the side wall 26 are made of, for example, a metal material such as aluminum alloy, and are formed into one body.

The inner cover 22 and the outer cover 23 are made of, for example, a metal material such as aluminum alloy. The inner cover 22 is attached to an end part of the side wall 26 by, for example, screws. The outer cover 23 covers the inner cover 22 and is air-tightly fixed to an end part of the side wall 26 by, for example, welding.

The case 11 is sealed. The case 11 contains the magnetic disks 12, the spindle motor 13, the clamp spring 14, the magnetic heads 15, the actuator assembly 16, the voice coil motor 17, the ramp load mechanism 18, and the FPC 19.

A vent hole 22a is provided in the inner cover 22. A vent hole 23a is provided in the outer cover 23. After components are mounted inside the base 21, and the inner cover 22 and the outer cover 23 are attached to the base 21, air in the case 11 is evacuated through the vent holes 22a and 23a. Then, gas that is different from ambient air is injected into the case 11.

The gas to be injected into the case 11 is, e.g., low-density gas having a density lower than that of the air, or an inert gas having low reactivity. In one example, helium is injected into the case 11. Alternatively, other fluid(s) may be injected into the case 11. In another example, the inside of the case 11 may be maintained at vacuum, a low pressure close to vacuum, or a negative pressure relative to the atmospheric pressure.

The vent hole 23a of the outer cover 23 is closed by a seal 28. The seal 28 air-tightly closes the vent hole 23a to prevent the fluid, which is injected into the case 11, from leaking from the vent hole 23a.

The magnetic disk 12 includes, for example, a magnetic recording layer provided on at least one of an upper surface and a lower surface. The diameter of the magnetic disk 12 is, for example, 3.5 inches, but is not limited to this.

The spindle motor 13 supports and rotates the multiple magnetic disks 12 that are stacked via spaces. The clamp spring 14 retains the multiple magnetic disks 12 to a hub of the spindle motor 13.

The magnetic head 15 records and reproduces information on and from the recording layer of the magnetic disk 12. In other words, the magnetic head 15 reads and writes information from and to the magnetic disk 12. The magnetic head 15 is supported by the actuator assembly 16.

The actuator assembly 16 is rotatably supported by a support shaft 31 that is disposed at a position separated from the magnetic disk 12. The voice coil motor 17 rotates the actuator assembly 16 and moves the actuator assembly 16 to a desired position. The voice coil motor 17 rotates the actuator assembly 16 to make the magnetic head 15 move to the outermost circumference of the magnetic disk 12. In response to this, the ramp load mechanism 18 holds the magnetic head 15 at an unloading position separated from the magnetic disk 12.

The actuator assembly 16 includes an actuator block 35, multiple arms 36, and multiple head suspension assemblies 37. The head suspension assembly 37 may also be called a “head gimbal assembly (HGA)” in some contexts.

The actuator block 35 is rotatably supported by the support shaft 31 via, for example, a bearing. The multiple arms 36 protrude in a direction approximately orthogonal to the support shaft 31 from the actuator block 35. Alternatively, the actuator assembly 16 may be disassembled, and the multiple arms 36 may respectively protrude from multiple actuator blocks 35.

The multiple arms 36 are arranged via spaces in the extending direction of the support shaft 31. Each of the arms 36 is formed into a plate shape that allows the arm 36 to enter the spaces between adjacent magnetic disks 12. The multiple arms 36 extend approximately parallel to each other.

The actuator block 35 and the multiple arms 36 are formed into one body by using, for example, aluminum. The materials for the actuator block 35 and the arm 36 are not limited to this example.

A voice coil of the voice coil motor 17 is provided at a protrusion that protrudes from the actuator block 35. The voice coil motor 17 includes a pair of yokes, the voice coil interposed between the yokes, and magnets provided in the yokes.

The head suspension assembly 37 is attached at an end part of a corresponding arm 36 and protrudes from the arm 36. Thus, the multiple head suspension assemblies 37 are arranged via spaces in the extending direction of the support shaft 31.

Each of the multiple head suspension assemblies 37 includes a base plate 41, a load beam 42, and a flexure 43. In addition, the magnetic head 15 is attached to the head suspension assembly 37.

The base plate 41 and the load beam 42 are made of, for example, stainless steel. The materials for the base plate 41 and the load beam 42 are not limited to this example. The base plate 41 is formed into a plate shape and is attached at an end part of the arm 36. The load beam 42 is formed into a plate shape that is thinner than the base plate 41. The load beam 42 is attached at an end part of the base plate 41 and protrudes from the base plate 41.

The flexure 43 is formed into a long narrow strip shape. The shape of the flexure 43 is not limited to this example. The flexure 43 is a stacked plate including a metal plate as a backing layer, an insulating layer, a conductive layer, and a protective layer as an insulating layer. The metal plate is made of stainless or other material. The insulating layer is formed on the metal plate. The conductive layer is formed on the insulating layer and includes multiple wirings or wiring patterns. The protective layer covers the conductive layer.

One end of the flexure 43 is provided with a gimbal part or an elastic support. The gimbal part is positioned on the load beam 42 and is displaceable. The magnetic head 15 is mounted on the gimbal part. The other end of the flexure 43 is coupled to the FPC 19. Thus, the FPC 19 is electrically connected to the magnetic head 15 via the wiring of the flexure 43.

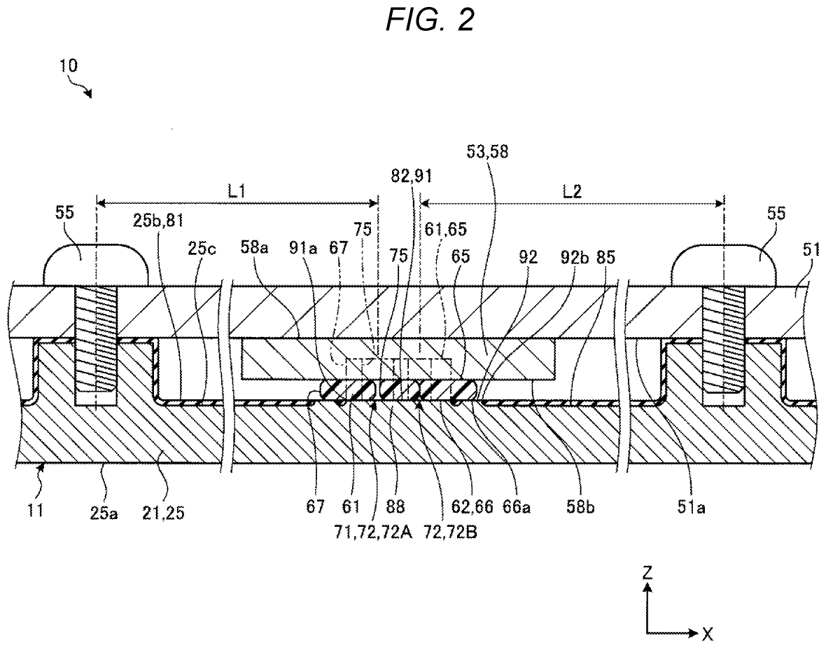

FIG. 2 is a sectional view schematically showing a part of the HDD 10 of the first embodiment. As shown in FIGS. 1 and 2, the HDD 10 further includes a printed circuit board (PCB) 51, an interface (I/F) connector 52, multiple electronic components 53, a relay connector 54, and multiple screws 55. The PCB 51 is an example of a board. The screw 55 is an example of a mounting member.

The PCB 51 is, for example, a rigid board, such as a glass epoxy board, and the PCB 51 is, e.g., a multilayered board or a build-up board. As shown in FIG. 2, the PCB 51 is disposed outside the case 11 and is mounted at an outside part of the bottom wall 25 of the base 21.

The PCB 51 is mounted to the bottom wall 25 by the multiple screws 55. The mounting member may be some other member such as a hook for mounting the PCB 51 to the bottom wall 25 by snap-fit.

The I/F connector 52 in FIG. 1 is in conformity with an interface standard such as Serial ATA and is coupled to an I/F connector of a host computer. The HDD 10 is supplied with power from the host computer via the I/F connector 52 and transceives various kinds of data with the host computer.

The multiple electronic components 53 include a controller 58. The multiple electronic components 53 may include, for example, a servo controller for driving the spindle motor 13 and the VCM 17, various kinds of memories, such as a RAM, a ROM, and a buffer memory, and other electronic components such as a coil and a capacitor.

The controller 58 is, for example, an integrated circuit (e.g., a large-scale integration, LSI circuit), and includes a read/write channel (RWC), a hard disk controller (HDC), and a processor. The RWC, the HDC, and the processor may be separate components.

The processor of the controller 58 is, for example, a central processing unit (CPU). The processor controls the entire HDD 10 in accordance with, e.g., firmware that is preliminarily stored in a ROM and the magnetic disk 12. In one example, the processor loads the firmware in the ROM and the magnetic disk 12 to a RAM and executes control of the magnetic head 15, the RWC, the HDC, and other components in accordance with the loaded firmware.

The relay connector 54 is electrically connected to various kinds of components that are arranged inside the case 11, via, for example, a connector provided in the bottom wall 25. Thus, the PCB 51 is electrically connected to the spindle motor 13, the magnetic head 15, the actuator assembly 16, the VCM 17, and the FPC 19, which are arranged inside the case 11, through the relay connector 54.

As shown in FIG. 2, the bottom wall 25 of the case 11 includes an inside surface 25a and an outside surface 25b. The inside surface 25a is formed approximately flat and faces the inside of the case 11. The outside surface 25b is positioned on a side opposite to the inside surface 25a. The outside surface 25b is formed approximately flat and faces the outside of the case 11. In addition, the outside surface 25b faces the PCB 51 via a space. The inside surface 25a and the outside surface 25b are approximately parallel to each other and extend on an X-Y plane. In FIG. 2, the inside surface 25a faces the −Z direction, whereas the outside surface 25b faces the +Z direction.

The PCB 51 includes a mounting surface 51a. The mounting surface 51a is formed into approximately flat and faces the outside surface 25b of the bottom wall 25 via a space. In FIG. 2, the mounting surface 51a faces the −Z direction. The mounting surface 51a is mounted with the multiple electronic components 53, including the controller 58. Thus, the controller 58 is positioned between the outside surface 25b of the bottom wall 25 and the mounting surface 51a of the PCB 51. At least one of the multiple electronic components 53 may be mounted on a part that is different from the mounting surface 51a of the PCB 51.

The controller 58 includes a first surface 58a and a second surface 58b. The second surface 58b is an example of a facing surface. The first surface 58a faces the mounting surface 51a of the PCB 51. The first surface 58a may be provided with a terminal. The first surface 58a may be in contact with the mounting surface 51a or may be separated from the mounting surface 51a. The second surface 58b is positioned on a side opposite to the first surface 58a. The second surface 58b faces the outside surface 25b of the bottom wall 25 via a space. In FIG. 2, the first surface 58a faces the +Z direction, whereas the second surface 58b faces the −Z direction.

The HDD 10 further includes a heat dissipation sheet 61. The heat dissipation sheet 61 is an example of a heat conduction member. The heat dissipation sheet 61 is made of, for example, synthetic resin with high thermal conductivity, such as acrylic rubber. Alternatively, the heat dissipation sheet 61 may be made of other material. The thermal conductivity of the heat dissipation sheet 61 is at least higher than that of the air.

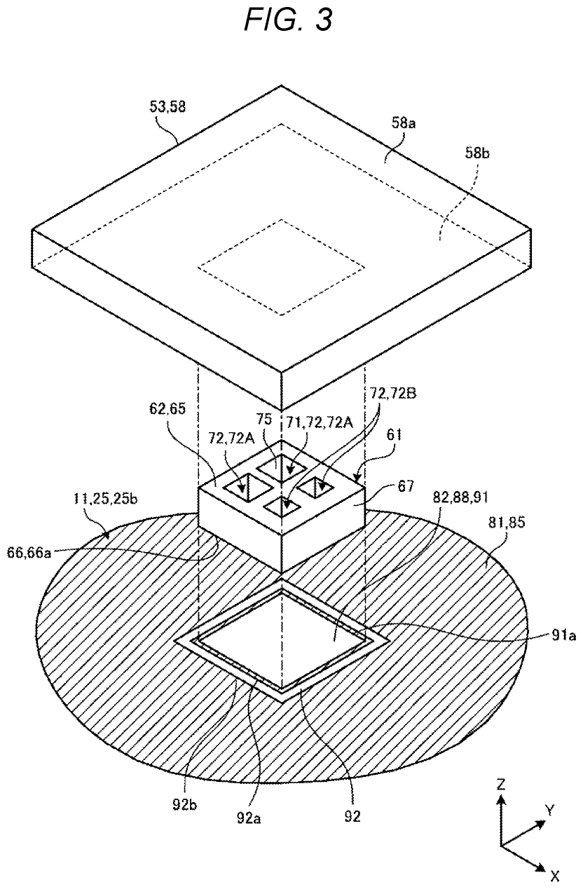

FIG. 3 is an exploded perspective view of the bottom wall 25, the controller 58, and the heat dissipation sheet 61 of the first embodiment. As shown in FIG. 3, the heat dissipation sheet 61 is formed into, for example, an approximately rectangular parallelepiped shape. The shape of the heat dissipation sheet 61 is not limited to this example.

As shown in FIG. 2, the heat dissipation sheet 61 includes a surface 62. The surface 62 is an outside surface facing the outside of the heat dissipation sheet 61. The surface 62 includes a first contact surface 65, a second contact surface 66, and a side surface 67. The second contact surface 66 is an example of each of a second contact surface and a contact surface.

The first contact surface 65 faces and is in contact with the second surface 58b of the controller 58. In FIG. 2, the first contact surface 65 is an end surface in the +Z direction of the heat dissipation sheet 61 and faces the +Z direction. The first contact surface 65 has, for example, adhesiveness, and is affixed to the second surface 58b. The first contact surface 65 is not limited by this example.

The second contact surface 66 is positioned on a side opposite to the first contact surface 65. The second contact surface 66 faces and is in contact with the outside surface 25b of the bottom wall 25. In FIG. 2, the second contact surface 66 is an end surface in the −Z direction of the heat dissipation sheet 61 and faces the −Z direction. The second contact surface 66 has, for example, adhesiveness, and is affixed to the outside surface 25b. The second contact surface 66 is not limited by this example.

The heat dissipation sheet 61, which is in contact with the second surface 58b of the controller 58 and the outside surface 25b of the bottom wall 25, thermally couples the controller 58 to the bottom wall 25 of the case 11. This allows conduction of heat between the controller 58 and the bottom wall 25 of the case 11 via the heat dissipation sheet 61. The controller 58 generates heat, for example, when arithmetic operations are executed therein. The heat that is generated from the controller 58 is conducted to the bottom wall 25 through the heat dissipation sheet 61. As a result, the controller 58 loses heat and is cooled. Another member may thermally couple the controller 58 to the heat dissipation sheet 61, or yet another member may thermally couple the heat dissipation sheet 61 to the bottom wall 25 of the case 11. Basically, the heat dissipation sheet 61 is provided in a path for conducting heat between the controller 58 and the bottom wall 25 of the case 11; however, the heat dissipation sheet 61 may be separated from at least one of the controller 58 and the bottom wall 25 of the case 11.

As shown in FIG. 3, when viewed in the Z direction, the heat dissipation sheet 61 is smaller than the controller 58. Thus, each of the first contact surface 65 and the second contact surface 66 is smaller than the first surface 58a and the second surface 58b of the controller 58. Alternatively, the heat dissipation sheet 61 may have dimensions that are the same as or larger than the dimensions of the controller 58 when viewed from the Z direction.

The side surface 67 is provided between the first contact surface 65 and the second contact surface 66. In FIG. 2, the side surface 67 faces approximately the X direction or the Y direction. In other words, the side surface 67 faces a direction along the outside surface 25b of the bottom wall 25, which is a direction approximately parallel to the outside surface 25b.

As shown in FIG. 3, the heat dissipation sheet 61 is provided with holes 71. The holes 71 include multiple through holes 72 in the first embodiment. The through hole 72 extends approximately in the Z direction and penetrates through the heat dissipation sheet 61 between the first contact surface 65 and the second contact surface 66. Thus, the through hole 72 opens at the first contact surface 65 and the second contact surface 66. The through hole 72 may extend in another direction.

The multiple through holes 72 include a first through hole 72A and a second through hole 72B. The first through hole 72A is larger than the second through hole 72B. Specifically, a cross sectional area orthogonal to the Z direction of the first through hole 72A is larger than that of the second through hole 72B. In addition, an inner circumferential length of the cross-section of the first through hole 72A taken orthogonal to the Z direction is longer than that of the second through hole 72B.

As shown in FIG. 2, the first through hole 72A is closer to the screw 55 than the second through hole 72B. Specifically, a distance L1 between the first through hole 72A and a screw 55 closest to the first through hole 72A is shorter than a distance L2 between the second through hole 72B and a screw 55 closest to the second through hole 72B.

The first through hole 72A, which is larger than the second through hole 72B, is provided closer to the screw 55 than the second through hole 72B. That is, the hole 71 that is closer to the screw 55 is larger in the heat dissipation sheet 61. The hole 71 is not limited by the example descried above. In one example, the width of the hole 71 may be increased as the hole 71 is closer to the screw 55.

The multiple through holes 72 each have a polygonal cross section orthogonal to the Z direction in the first embodiment. The polygonal shape is a square shape, for example. Alternatively, the polygonal shape is not limited to this example and may be a triangular, pentagonal, or other polygonal shape.

The heat dissipation sheet 61 further includes an inside surface 75 that forms the through hole 72. The inside surface 75 faces the inside of the through hole 72 in the direction along the outside surface 25b of the bottom wall 25. In FIG. 2, the inside surface 75 faces approximately the X direction or the Y direction. A part of the inside surface 75 and another part of the inside surface 75 face each other.

The heat dissipation sheet 61 is compressed between the second surface 58b of the controller 58 and the outside surface 25b of the bottom wall 25. Specifically, in a natural state in which the heat dissipation sheet 61 is not compressed between the second surface 58b of the controller 58 and the outside surface 25b of the bottom wall 25, the thickness of the heat dissipation sheet 61 is greater than a distance between the second surface 58b of the controller 58 and the outside surface 25b of the bottom wall 25. The thickness of the heat dissipation sheet 61 is defined by the distance between the first contact surface 65 and the second contact surface 66. FIG. 2 shows a heat dissipation sheet 61 in the natural state by a two-dot chain line in a virtual manner and also shows a compressed heat dissipation sheet 61 by a solid line.

The compressed heat dissipation sheet 61 is deformed between the second surface 58b of the controller 58 and the outside surface 25b of the bottom wall 25 and extends in the direction along the outside surface 25b. In other words, the compressed heat dissipation sheet 61 extends in a direction orthogonal to the Z direction, in which the second surface 58b and the outside surface 25b face each other, between the second surface 58b of the controller 58 and the outside surface 25b of the bottom wall 25. The heat dissipation sheet 61 may be elastically deformed or may be plastically deformed. In this embodiment, for example, the compressed heat dissipation sheet 61 is elastically restored to a shape close to the shape before it is compressed, to some extent, upon being released from compression. The compressed heat dissipation sheet 61 may be elastically restored to the shape before it was compressed or may remain having a compressed shape upon being released from compression.

The heat dissipation sheet 61 that is compressed in the Z direction flows in such a manner as to extend in the X-Y plane. Specifically, a part of the heat dissipation sheet 61 is protruded from the side surface 67 toward the outside of the heat dissipation sheet 61. This results in movement of the side surface 67 toward the outside of the heat dissipation sheet 61. Moreover, another part of the heat dissipation sheet 61 is protruded from the inside surface 75 toward the inside of the heat dissipation sheet 61. This results in movement of the inside surface 75 toward the inside of the heat dissipation sheet 61, whereby a cross section orthogonal to the Z direction of the hole 71 is reduced. Additionally, the inside surfaces 75 may be brought into contact with each other and may close the hole 71.

The extension of the compressed heat dissipation sheet 61 makes the first contact surface 65 and the second contact surface 66 larger than the first contact surface 65 and the second contact surface 66 of the heat dissipation sheet 61 in the natural state. That is, in accordance with compression of the heat dissipation sheet 61, the contact area between the heat dissipation sheet 61 and the controller 58 increases, and the contact area between the heat dissipation sheet 61 and the bottom wall 25 increases.

As shown in FIG. 3, the outside surface 25b of the bottom wall 25 includes a coated part 81 and an exposed part 82. FIG. 3 shows the coated part 81 by hatching, for convenience of description. The coated part 81 is a part of the metal bottom wall 25 that is coated with a paint 85. The paint 85 is, for example, an insulating paint. The thermal conductivity of the paint 85 is lower than that of the metal bottom wall 25. The exposed part 82 is a part at which metal of the bottom wall 25 is exposed while being enclosed by the coated part 81.

As shown in FIG. 2, for example, the bottom wall 25 further includes a bottom surface 25c and multiple protrusions 88. The bottom surface 25c is positioned on a side opposite to the inside surface 25a and faces the outside of the case 11. The bottom surface 25c is closer to the inside surface 25a than the outside surface 25b. The protrusion 88 protrudes from the bottom surface 25c.

The bottom surface 25c is covered with the paint 85, and an end surface of the protrusion 88 is exposed without being covered with the paint 85. Thus, the paint 85 provides the coated part 81 that is a part of the outside surface 25b, and the protrusion 88 forms the exposed part 82 that is the other part of the outside surface 25b. The coated part 81 and the exposed part 82 are not limited by these examples.

As shown in FIG. 3, the exposed part 82 of the first embodiment includes a first exposed part 91 and a second exposed part 92. The first exposed part 91 has approximately the same shape as the second contact surface 66 of the heat dissipation sheet 61 in the natural state. Specifically, the first exposed part 91 is formed into an approximately square shape with the same dimensions as or slightly larger than the second contact surface 66 of the heat dissipation sheet 61 in the natural state. The second exposed part 92 is formed into an approximately square frame shape enclosing the first exposed part 91 with an interval therebetween. The coated part 81 is provided between the first exposed part 91 and the second exposed part 92.

The second contact surface 66 of the heat dissipation sheet 61 in the natural state is in contact with and is affixed to the first exposed part 91. The first exposed part 91 is used for positioning the heat dissipation sheet 61. For this purpose, an edge 91a of the first exposed part 91 extends along an outside edge 66a of the second contact surface 66 of the heat dissipation sheet 61 in the natural state. The edge 91a is an example of a first edge.

The outside edge 66a of the second contact surface 66 forms an outer circumference of the second contact surface 66. The second contact surface 66 includes multiple inside edges that form open ends of the multiple through holes 72. The inside edge and the outside edge 66a are separated from each other in this embodiment.

Each of the edge 91a of the first exposed part 91 and the outside edge 66a of the second contact surface 66 of the heat dissipation sheet 61 in the natural state is formed into an approximately square shape. The outside edge 66a is overlaid on the edge 91a or is positioned on the first exposed part 91 slightly separately from the edge 91a. The outside edge 66a and the edge 91a extend approximately parallel to each other. The extending direction of the edge 91a and the extending direction of the outside edge 66a may be slightly different from each other.

The second exposed part 92 includes an inside edge 92a and an outside edge 92b. The outside edge 92b is an example of a second edge. The inside edge 92a forms an inner circumference of the second exposed part 92 and is in contact with the coated part 81 between the first exposed part 91 and the second exposed part 92. The outside edge 92b forms an outer circumference of the second exposed part 92 and is in contact with the coated part 81 enclosing the second exposed part 92.

The second exposed part 92 is separated from the heat dissipation sheet 61 that is affixed to the first exposed part 91 and that is in the natural state. Thus, the inside edge 92a and the outside edge 92b of the second exposed part are more separated from the outside edge 66a of the second contact surface 66 of the heat dissipation sheet 61 in the natural state than the edge 91a of the first exposed part 91.

As shown in FIG. 2, the heat dissipation sheet 61 is compressed between the second surface 58b of the controller 58 and the outside surface 25b of the bottom wall 25 and extends in the direction along the outside surface 25b, as described above. As a result, the compressed heat dissipation sheet 61 crosses over the coated part 81, which encloses the first exposed part 91, and is brought into contact with the second exposed part 92.

The outside edge 92b of the second exposed part 92 has approximately the same shape as the outside edge 66a of the second contact surface 66 of the compressed heat dissipation sheet 61. Thus, the outside edge 92b of the second exposed part 92 extends along the outside edge 66a of the second contact surface 66 of the heat dissipation sheet 61 that is in the condition of being compressed between the second surface 58b of the controller 58 and the outside surface 25b of the bottom wall 25.

The outside edge 66a of the second contact surface 66 is overlaid on the outside edge 92b of the second exposed part 92 or is positioned on the second exposed part 92 slightly separately from the outside edge 92b. The outside edge 66a and the outside edge 92b extend approximately parallel to each other. The extending direction of the outside edge 92b and the extending direction of the outside edge 66a may be slightly different from each other.

As described above, the heat dissipation sheet 61 is positioned by the first exposed part 91 and is affixed thereto in assembling. In response to mounting the PCB 51, which is mounted with the controller 58, to the bottom wall 25, the heat dissipation sheet 61 is compressed between the second surface 58b of the controller 58 and the outside surface 25b of the bottom wall 25. The heat dissipation sheet 61 that is extended by compression comes into contact with the second exposed part 92 as well as the first exposed part 91. This improves efficiency of heat conduction between the heat dissipation sheet 61 and the bottom wall 25.

In the HDD 10 according to the first embodiment described above, the heat dissipation sheet 61 is compressed between the controller 58 and the outside surface 25b of the case 11 and thermally couples the controller 58 to the case 11. The compressed heat dissipation sheet 61 is deformed and extends in the direction along the outside surface 25b of the case 11 between the controller 58 and the case 11. The heat dissipation sheet 61 is provided with the hole 71. In response to compression of the heat dissipation sheet 61, an outside edge part of the heat dissipation sheet 61, including the side surface 67, is protruded outwardly, and an inside edge part of the heat dissipation sheet 61, including the inside surface 75 for forming the hole 71, is protruded inwardly. In this case, parts that are able to be deformed and be extended increase in the heat dissipation sheet 61, compared with a case of not providing the hole 71. Thus, the compressed heat dissipation sheet 61 is more easily deformed, and this reduces the reaction forces acting from the compressed heat dissipation sheet 61 to the controller 58 and the PCB 51 and to the case 11. When the reaction forces acting on the controller 58 and the PCB 51 and on the case 11 are great, there are risks that the PCB 51 and the bottom wall 25 of the case 11 are deformed in such a manner as to be warped and stress at a coupled part of the controller 58 and the PCB 51 increases. On the other hand, in the HDD 10 of this embodiment, the reaction forces are reduced as described above, and this enables reducing deformation of the PCB 51 and the bottom wall 25 of the case 11 as well as preventing increase in stress at the coupled part of the controller 58 and the PCB 51.

The holes 71 include the through hole 72 that penetrates through the heat dissipation sheet 61. This structure enlarges the inside edge part, that is, the inside surface 75 of the heat dissipation sheet 61. Thus, the compressed heat dissipation sheet 61 is more easily deformed, and this reduces the reaction forces acting from the compressed heat dissipation sheet 61 to the controller 58 and the PCB 51 and to the case 11.

The heat dissipation sheet 61 includes the first contact surface 65 to be in contact with the controller 58 and the second contact surface 66 to be in contact with the outside surface 25b. The through hole 72 penetrates through the heat dissipation sheet 61 between the first contact surface 65 and the second contact surface 66. In this case, the reaction force acting from the first contact surface 65 to the controller 58 is better distributed at the first contact surface 65, and the reaction force acting from the second contact surface 66 to the outside surface 25b is better distributed at the second contact surface 66, compared with a case in which the through hole 72 penetrates through the heat dissipation sheet 61 in the direction along the outside surface 25b. Moreover, the heat dissipation sheet 61 that is provided with the hole 71 is easy to manufacture. In one example, multiple heat dissipation sheets 61 can be manufactured by cutting a larger sheet with multiple holes 71 that are provided in approximately parallel to each other.

The controller 58 includes the second surface 58b that faces the outside surface 25b. The heat dissipation sheet 61 includes the first contact surface 65 to be in contact with the second surface 58b and the second contact surface 66 to be in contact with the outside surface 25b. The first contact surface 65 is smaller than the second surface 58b. In other words, for example, the heat dissipation sheet 61 is smaller than the controller 58, and the outside edges of the heat dissipation sheet 61 are enclosed by the outside edges of the controller 58, when viewed in the +Z direction along the Z direction from the outside surface 25b to the mounting surface 51a. The heat dissipation sheet 61 is thus formed relatively small. The heat dissipation sheet 61 is generally more easily deformed as it is smaller. Thus, the compressed heat dissipation sheet 61 is more easily deformed, and this reduces the reaction forces acting from the compressed heat dissipation sheet 61 to the controller 58 and the PCB 51 and to the case 11.

In this embodiment, the heat dissipation sheet 61 is provided with the hole 71, and therefore, the areas of the first contact surface 65 and the second contact surface 66 are decreased compared with a case of not providing the hole 71. However, the areas of the first contact surface 65 and the second contact surface 66 are set in accordance with a set amount of heat to be conducted between the controller 58 and the case 11. For this reason, in this embodiment in which the hole 71 is provided, the areas of the first contact surface 65 and the second contact surface 66 are set to be large as much as possible in accordance with the set amount of heat to be conducted. The first contact surface 65 is smaller than the second surface 58b of the controller 58. This prevents the first contact surface 65 from protruding out of the second surface 58b of the controller 58 although the areas of the first contact surface 65 and the second contact surface 66 are set large.

The PCB 51 is mounted to the case 11 by the multiple screws 55. The heat dissipation sheet 61 is compressed between the controller 58 and the outside surface 25b. Thus, the PCB 51 is deformed by the reaction force of the heat dissipation sheet 61, in such a manner as to be warped. As the controller 58 is closer to the screw 55, the distance between the controller 58 and the outside surface 25b decreases, and a load acting on the heat dissipation sheet increases. In this embodiment, the hole 71 that is closer to the screw 55 is larger in the heat dissipation sheet 61. In these conditions, as the heat dissipation sheet 61 is closer to the screw 55, the heat dissipation sheet 61 is more easily deformed, and the reaction forces acting from the heat dissipation sheet 61 to the controller 58 and the PCB 51 and to the case 11 are reduced and are better distributed.

The hole 71 has a polygonal cross section. The outer circumference of the polygonal shape is longer than a circumference of a circle having the same area as the polygonal shape. For this reason, an inside edge part of the heat dissipation sheet 61 can be set large compared with a case in which the hole 71 is circular, in the HDD 10 of this embodiment. Specifically, an outer circumference of a cross section orthogonal to the Z direction of the hole 71 is made long. Thus, the compressed heat dissipation sheet 61 is more easily deformed, and this reduces the reaction forces acting from the compressed heat dissipation sheet 61 to the controller 58 and the PCB 51 and to the case 11.

The outside surface 25b includes the exposed part 82 at which the metal is exposed. The heat dissipation sheet 61 includes the second contact surface 66 to be in contact with the exposed part 82. The edge 91a of the first exposed part 91, which is included in the exposed part 82, extends along the outside edge 66a of the second contact surface 66 of the heat dissipation sheet 61 that is in the condition of not being compressed between the controller 58 and the outside surface 25b. Compared with the edge 91a, the outside edge 92b of the second exposed part 92, which is included in the exposed part 82, is separated from the outside edge 66a of the second contact surface 66 of the heat dissipation sheet 61 that is in the condition of not being compressed between the controller 58 and the outside surface 25b. Moreover, the outside edge 92b extends along the outside edge 66a of the second contact surface 66 of the heat dissipation sheet 61 that is in the condition of being compressed between the controller 58 and the outside surface 25b. Attaching the heat dissipation sheet 61 to the case 11 with reference to the edge 91a enables a more exact arrangement of the heat dissipation sheet 61 at a desired position. Moreover, the heat dissipation sheet 61 that is extended by deformation is in contact with the exposed part 82 by a larger contact area. This improves heat dissipation performance of the heat dissipation sheet 61 with respect to the controller 58.

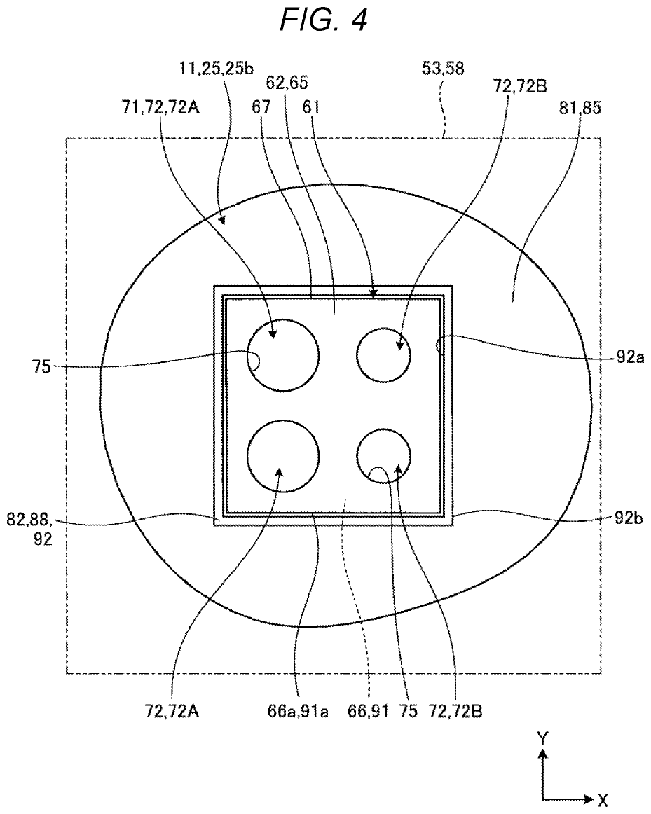

FIG. 4 is a plan view schematically showing the bottom wall 25, the controller 58, and the heat dissipation sheet according to a modification example of the first embodiment. FIG. 4 shows the controller 58 by a two-dot chain line in a virtual manner. As shown in FIG. 4, the cross section orthogonal to the Z direction of the through hole 72 may be circular. In this case, the hole 71 can be easily formed by, for example, drilling with a drill or punching.

### Second Embodiment

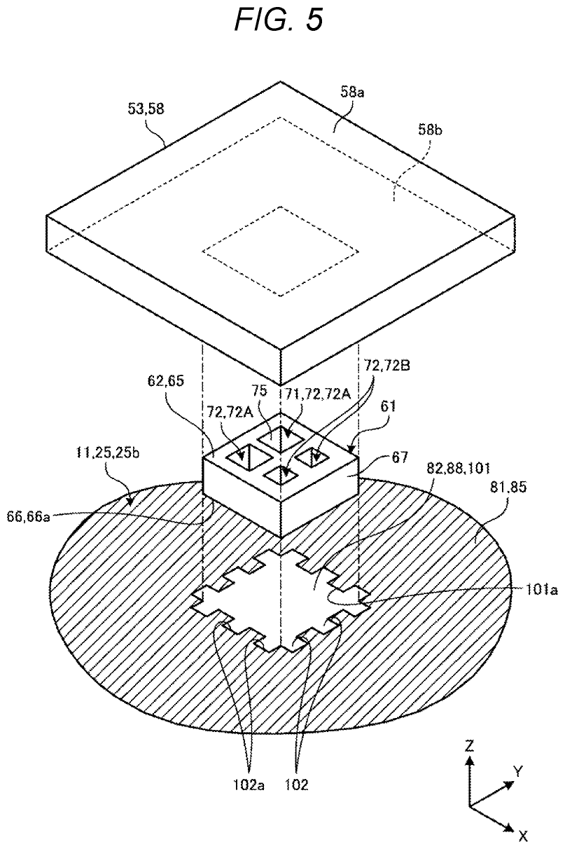

Hereinafter, a second embodiment will be described with reference to FIG. 5. In the following description of multiple embodiments, elements having functions similar to those of the already described elements are denoted by the same reference signs as those of the already described elements, and descriptions thereof may be omitted. In addition, multiple elements having the same reference signs may not have exactly the same functions and characteristics and may have different functions and characteristics in accordance with each embodiment.

FIG. 5 is an exploded perspective view of the bottom wall 25, the controller 58, and the heat dissipation sheet 61 according to the second embodiment. As shown in FIG. 5, the exposed part 82 of the second embodiment includes a third exposed part 101 and multiple fourth exposed parts 102 instead of the first exposed part 91 and the second exposed part 92.

The third exposed part 101 has approximately the same shape as the second contact surface 66 of the heat dissipation sheet 61 in the natural state. Specifically, the third exposed part 101 is formed into an approximately square shape with the same dimensions as or slightly larger than the second contact surface 66 of the heat dissipation sheet 61 in the natural state.

The second contact surface 66 of the heat dissipation sheet 61 in the natural state is in contact with and is affixed to the third exposed part 101. That is, the third exposed part 101 is used for positioning the heat dissipation sheet 61. For this purpose, an edge 101a of the third exposed part 101 extends along the outside edge 66a of the second contact surface 66 of the heat dissipation sheet 61 in the natural state. The edge 101a is an example of the first edge.

Each of the multiple fourth exposed parts 102 is formed into an approximately square shape that is smaller than the third exposed part 101. The fourth exposed part 102 is not limited by this example. The fourth exposed part 102 is contiguous with the third exposed part 101 and protrudes from the edge 101a of the third exposed part 101. In addition, the multiple fourth exposed parts 102 are separated from each other.

Each of the multiple fourth exposed parts 102 has an outside edge 102a. The outside edge 102a is an example of the second edge. The outside edge 102a extends approximately parallel to the edge 101a of the third exposed part 101.

The fourth exposed part 102 is separated from the heat dissipation sheet 61 that is affixed to the third exposed part 101 and that is in the natural state. The outside edge 102a of the fourth exposed part 102 is more separated from the outside edge 66a of the second contact surface 66 of the heat dissipation sheet 61 in the natural state than the edge 101a of the third exposed part 101.

The outside edge 102a of the fourth exposed part 102 has a shape corresponding to the outside edge 66a of the second contact surface 66 of the compressed heat dissipation sheet 61. The outside edge 102a of the fourth exposed part 102 extends along the outside edge 66a of the second contact surface 66 of the heat dissipation sheet 61 that is in the condition of being compressed between the second surface 58b of the controller 58 and the outside surface 25b of the bottom wall 25.

The heat dissipation sheet 61 is positioned by the third exposed part 101 and is affixed thereto in assembling. In response to mounting the PCB 51, which is mounted with the controller 58, to the bottom wall 25, the heat dissipation sheet 61 is compressed between the second surface 58b of the controller 58 and the outside surface 25b of the bottom wall 25. The heat dissipation sheet 61 that is extended by compression comes into contact with the multiple fourth exposed parts 102 as well as the third exposed part 101. This improves efficiency of heat conduction between the heat dissipation sheet 61 and the bottom wall 25.

In the HDD 10 of the second embodiment described above, the third exposed part 101 and the fourth exposed part 102 are contiguous with each other. This makes it easier to form the third exposed part 101, which is used for positioning the heat dissipation sheet 61, and the fourth exposed part 102, which is to be brought into contact with the extended heat dissipation sheet 61.

### Third Embodiment

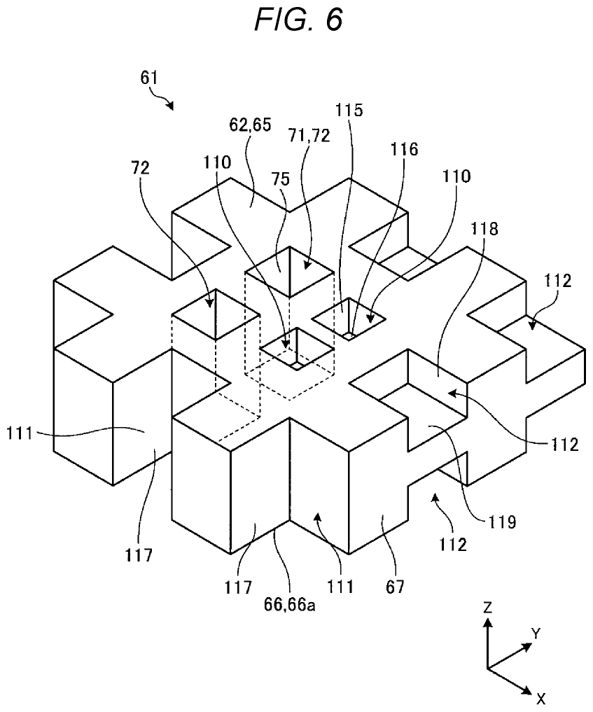

Hereinafter, a third embodiment will be described with reference to FIG. 6. FIG. 6 is a perspective view schematically showing the heat dissipation sheet 61 of the third embodiment. As shown in FIG. 6, the holes 71 of the third embodiment include multiple recesses 110, multiple first cut-off parts 111, and multiple second cut-off parts 112 in addition to the through hole 72.

The multiple recesses 110 are closed holes that are recessed from at least one of the first contact surface 65 and the second contact surface 66. In other words, the recess 110 opens at at least one of the first contact surface 65 and the second contact surface 66. The part that is formed with the recess 110 is thinner than the other part in the heat dissipation sheet 61.

The heat dissipation sheet 61 also includes an inside surface 115 and a bottom surface 116 that form the recess 110. The inside surface 115 faces the inside of the recess 110 in the direction along the outside surface 25b of the bottom wall 25. In FIG. 6, the inside surface 115 faces approximately the X direction or the Y direction. A part of the inside surface 115 and another part of the inside surface 115 face each other. The bottom surface 116 is positioned at an inner part of the heat dissipation sheet 61 and faces the outside of the heat dissipation sheet 61. The bottom surface 116 faces the Z direction in FIG. 6.

Each of the first cut-off part 111 and the second cut-off part 112 opens to the side surface 67. In other words, each of the first cut-off part 111 and the second cut-off part 112 is recessed from the side surface 67 to the inside of the heat dissipation sheet 61.

The first cut-off part 111 extends approximately in the Z direction and penetrates through the heat dissipation sheet 61 between the first contact surface 65 and the second contact surface 66. That is, the first cut-off part 111 opens to the first contact surface 65, the second contact surface 66, and the side surface 67.

The heat dissipation sheet 61 further includes an inside surface 117 that forms the first cut-off part 111. The inside surface 117 faces the inside of the first cut-off part 111 in the direction along the outside surface 25b of the bottom wall 25. A part of the inside surface 117 and another part of the inside surface 117 face each other. Moreover, a part of the inside surface 117 faces the outside of the heat dissipation sheet 61 via an open end of the first cut-off part 111 of the side surface 67.

The second cut-off part 112 is recessed approximately in the Z direction from either one of the first contact surface 65 or the second contact surface 66. That is, the second cut-off part 112 opens to either one of the first contact surface 65 or the second contact surface 66 and to the side surface 67.

The heat dissipation sheet 61 further includes an inside surface 118 and a bottom surface 119 that form the second cut-off part 112. The inside surface 118 faces the inside of the second cut-off part 112 in the direction along the outside surface 25b of the bottom wall 25. A part of the inside surface 118 and another part of the inside surface 118 face each other. Moreover, a part of the inside surface 118 faces the outside of the heat dissipation sheet 61 via an open end of the second cut-off part 112 of the side surface 67. The bottom surface 119 is positioned at an inner part of the heat dissipation sheet 61 and faces the outside of the heat dissipation sheet 61. The bottom surface 119 faces the Z direction in FIG. 6.

The part that is provided with the through hole 72 or the first cut-off part 111 is more easily deformed than the part that is provided with the recess 110 or the second cut-off part 112 in the heat dissipation sheet 61. The through hole 72 and the first cut-off part 111 are closer to the screw 55 than the recess 110 and the second cut-off part 112. The positions of the through hole 72, the recess 110, the first cut-off part 111, and the second cut-off part 112 are not limited to these examples.

In the example in FIG. 6, each of the through hole 72, the recess 110, the first cut-off part 111, and the second cut-off part 112 has an approximately square cross section orthogonal to the Z direction. However, each of the through hole 72, the recess 110, the first cut-off part 111, and the second cut-off part 112 may have a cross section of another shape, such as circle.

In the HDD 10 of the third embodiment described above, the heat dissipation sheet 61 includes the surface 62. The holes 71 include the recess 110 that is recessed from the surface 62. This reduces decrease in volume of the heat dissipation sheet 61 due to formation of the hole 71, thereby preventing reduction in amount of heat that can be stored by the heat dissipation sheet 61. Thus, decrease in heat dissipation performance of the heat dissipation sheet 61 with respect to the controller 58 is suppressed.

The holes 71 include at least one recess 110 that is recessed from at least one of the first contact surface 65 and the second contact surface 66. In this case, the reaction force acting from the first contact surface 65 to the controller 58 is more distributed at the first contact surface 65, and the reaction force acting from the second contact surface 66 to the outside surface 25b is more distributed at the second contact surface 66, compared with a case in which the recess 110 is recessed from the surface 62 of the heat dissipation sheet 61 in the direction along the outside surface 25b. Moreover, the heat dissipation sheet 61 that is provided with the hole 71 is easier to be manufactured.

The heat dissipation sheet 61 includes the side surface 67 that is provided between the first contact surface 65 and the second contact surface 66. The holes 71 include the first cut-off part 111 and the second cut-off part 112 that open to the side surface 67. That is, the hole 71 that opens to the outside makes it easier for the heat dissipation sheet 61 to be deformed in such a manner as to extend in the direction along the outside surface 25b. Thus, the compressed heat dissipation sheet 61 is more easily deformed, and this reduces the reaction forces acting from the compressed heat dissipation sheet 61 to the controller 58 and the PCB 51 and to the case 11. Moreover, gas that is thermally expanded inside the hole 71 can be released to the outside of the heat dissipation sheet 61.

In one example, multiple shallow recesses 110 may be provided in the heat dissipation sheet 61 by embossing. Providing such recesses 110 also increases parts that are able to be deformed and be extended in the heat dissipation sheet 61, compared with a case of not providing the hole 71. Thus, the compressed heat dissipation sheet 61 is more easily deformed, and this reduces the reaction forces acting from the compressed heat dissipation sheet 61 to the controller 58 and the PCB 51 and to the case 11.

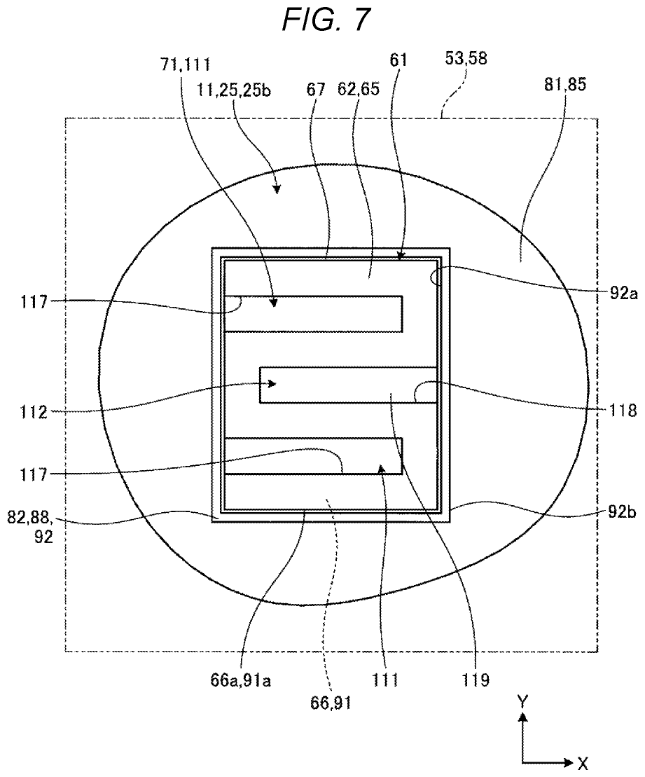

FIG. 7 is a plan view schematically showing the bottom wall 25, the controller 58, and the heat dissipation sheet 61 according to a first modification example of the third embodiment. As shown in FIG. 7, each of the first cut-off part 111 and the second cut-off part 112 may include an approximately rectangular cross section orthogonal to the Z direction.

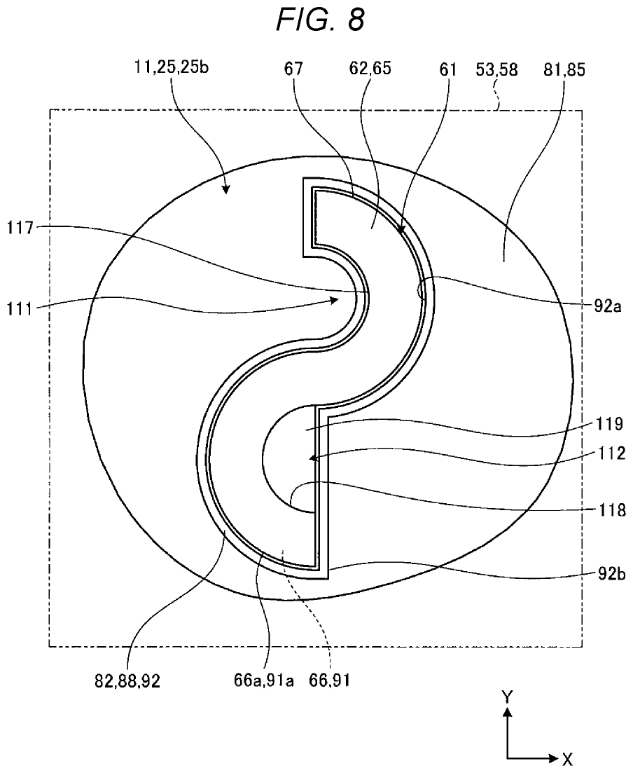

FIG. 8 is a plan view schematically showing the bottom wall 25, the controller 58, and the heat dissipation sheet 61 according to a second modification example of the third embodiment. As shown in FIG. 8, each of the first cut-off part 111 and the second cut-off part 112 may include an approximately semicircular cross section orthogonal to the Z direction. In other words, each of the first cut-off part 111 and the second cut-off part 112 may include a circular arc-shaped part.

As in these multiple embodiments, the holes 71 may include the through hole 72, the recess 110, the first cut-off part 111 and the second cut-off part 112. The holes 71 may further include a groove, a slit, a hollow, an opening, and a hole that is represented by other expression.

In at least one of the embodiments described above, the heat conduction member is compressed between the electronic component and the outside surface of the case and thermally couples the electronic component to the case. The compressed heat conduction member is deformed and extends in the direction along the outside surface of the case between the electronic component and the case. The heat conduction member is provided with the hole. In response to compression of the heat conduction member, the outside edge part of the heat conduction member is protruded outwardly, and the inside edge part of the heat conduction member, which forms the hole, is protruded inwardly. In this case, parts that are able to be deformed and be extended increase in the heat conduction member, compared with a case of not providing the hole. Thus, the compressed heat conduction member is more easily deformed, and this reduces the reaction forces acting from the compressed heat conduction member to the electronic component and the board and to the case. When the reaction forces acting on the electronic component and the board and on the case are great, there is a risk that the board and the case will become deformed in such a manner as to be warped and stresses at a coupled part of the electronic component and the board will increase. On the other hand, in the disk drive of the embodiments of the present disclosure, the reaction forces are reduced as described above, and this enables reducing deformation of the board and the case and preventing increase in stress at the coupled part of the electronic component and the board.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A disk drive, comprising:
a case having an outer surface;
a recording medium disposed inside the case and having a recording layer;
a magnetic head disposed inside the case and configured to read and write information from and to the recording medium;
a board disposed outside the case, having a mounting surface that faces the outer surface, and electrically connected to the magnetic head;
an electronic component mounted on the mounting surface; and
a heat conduction member having a hole and compressed between the electronic component and the outer surface in a thickness direction of the disk drive to thermally couple the electronic component to the case.

2. The disk drive according to claim 1, wherein the hole penetrates through the heat conduction member in the thickness direction.

3. The disk drive according to claim 2, wherein
the heat conduction member includes a first contact surface in contact with the electronic component and a second contact surface in contact with the outer surface, and
the hole penetrates through the heat conduction member and extends between the first contact surface and the second contact surface.

4. The disk drive according to claim 1, wherein the hole is recessed from a surface of the heat conduction member that faces one of the electronic component and the outer surface and does not penetrate entirely through the heat conduction member in the thickness direction.

5. The disk drive according to claim 4, wherein the surface includes one of a first contact surface in contact with the electronic component and a second contact surface in contact with the outside surface.

6. The disk drive according to claim 5, wherein
the heat conduction member includes a side surface between the first contact surface and the second contact surface, and
the hole extends to the side surface.

7. The disk drive according to claim 1, wherein
the electronic component includes a facing surface that faces the outer surface,
the heat conduction member includes a first contact surface in contact with the facing surface and a second contact surface in contact with the outer surface, and
the first contact surface is smaller than the facing surface.

8. The disk drive according to claim 7, further comprising:
multiple mounting members for mounting the board to the case, wherein
the heat conduction member has one or more additional holes, and
a first hole of which is closer to the mounting member than a second hole and is larger than the second hole.

9. The disk drive according to claim 1, wherein the hole has a circular cross section.

10. The disk drive according claim 1, wherein the hole has a polygonal cross section.

11. The disk drive according to claim 1, wherein
the case is formed of metal and the outer surface includes a coated part and an exposed part that is enclosed by the coated part, the metal being exposed at the exposed part, and
the heat conduction member includes a contact surface in contact with the exposed part.

12. The disk drive according to claim 11, wherein
the exposed part includes an inner exposed part and an outer exposed part,
the inner exposed part including a first edge that extends along an outside edge of the contact surface of the heat conduction member before it has been compressed between the electronic component and the outer surface, and
the outer exposed part including a second edge that is separated from the outside edge of the contact surface of the heat conduction member before it has been compressed between the electronic component and the outer surface and extends along the outside edge of the contact surface of the heat conduction member when it is compressed between the electronic component and the outer surface.

13. The disk drive according to claim 12, wherein the inner exposed part and the outer exposed part are separated by a region at which the metal is not exposed.

14. A disk drive, comprising:
a case having an outer surface;
a recording medium disposed inside the case and having a recording layer;
a magnetic head disposed inside the case and configured to read and write information from and to the recording medium;
a board disposed outside the case, having a mounting surface that faces the outer surface, and electrically connected to the magnetic head;
an electronic component mounted on the mounting surface; and
a heat conduction member between the electronic component and the outside surface in a thickness direction of the disk drive, the heat conduction member including a first contact surface in contact with the electronic component and a second contact surface in contact with the outside surface, and having a hole that opens to at least one of the first contact surface and the second contact surface.

15. The disk drive according to claim 14, wherein the hole opens to both the first contact surface and the second contact surface.

16. The disk drive according to claim 14, wherein the hole is recessed from one of the first contact surface and the second contact surface.

17. The disk drive according to claim 16, wherein the heat conduction member includes a side surface between the first contact surface and the second contact surface, and the hole extends to the side surface.

18. The disk drive according to claim 14, wherein
the electronic component includes a facing surface that faces the outer surface, and
the first contact surface is smaller than the facing surface.

19. The disk drive according to claim 14, wherein the hole has a circular cross section.

20. The disk drive according claim 14, wherein the hole has a polygonal cross section.
